(19) United States
(12) Patent Application Publication
(10) Pub. No.: US 2014/0293254 A1
(43) Pub. Date: Oct. 2, 2014

(54) ILLUMINATION OPTICAL DEVICE, OPTICAL UNIT, ILLUMINATION METHOD, AND EXPOSURE METHOD AND DEVICE

(71) Applicant: NIKON CORPORATION, Tokyo (JP)

(72) Inventor: Hideki KOMATSUDA, Ageo-shi (JP)

(21) Appl. No.: 14/205,649

(22) Filed: Mar. 12, 2014

Related U.S. Application Data
(63) Continuation of application No. PCT/JP2012/073745, filed on Sep. 14, 2012.
(60) Provisional application No. 61/535,654, filed on Sep. 16, 2011.

(51) Int. Cl. G03F 7/20; G02B 26/06; G02B 27/09; G02B 27/28

(52) U.S. Cl. CPC G03F 7/70058; G02B 27/283; G02B 26/06; G02B 27/0927
USPC 355/67; 359/238; 359/291; 355/77

(57) ABSTRACT

An illumination device for illuminating a reticle surface as an illumination target surface with illumination light supplied from a light source is provided with a first polarization beam splitter for separating the illumination light into a first beam and a second beam with respective polarization directions orthogonal to each other; a deformable mirror which is arranged in an optical path of the second beam and a shape of a reflecting surface of which is variable for changing a phase difference distribution between the first beam and the second beam; and a second polarization beam splitter for combining the first beam and the second beam between which the phase difference distribution has been established. The illumination target surface can be illuminated with light having a distribution of various polarization states.

### TECHNICAL FIELD

The present invention relates to an illumination technology for illuminating an illumination target surface with light supplied from a light source, an optical technology for changing a polarization state of the light supplied from the light source, an exposure technology making use of the illumination technology or the optical technology, and a device manufacturing technology making use of this exposure technology.

### BACKGROUND ART

For example, an exposure apparatus such as a stepper or a scanning stepper used in the lithography process for manufacturing electronic devices (micro devices) such as semiconductor devices is provided with an illumination optical apparatus for illuminating a reticle (mask) under various illumination conditions and in a uniform illuminance distribution. A conventional illumination optical apparatus was provided with an intensity distribution setting optical system having a plurality of interchangeable diffractive optical elements (Diffractive Optical Element) or a spatial light modulator of a movable multi-mirror system (spatial light modulator) having a large number of microscopic mirror elements whose inclination angles are variable, in order to set a light intensity distribution on a pupil plane of an illumination optical system to a distribution in which intensity is high in a circular region, an annular region, a multi-pole region, or the like, according to an illumination condition.

A recently-proposed illumination optical apparatus for further enhancing the resolution is one configured, for example, so that each of beams is divided into two beams with orthogonal polarization directions (ordinary ray and extraordinary ray) by a birefringent crystal and the two divided beams are individually reflected to illuminate predetermined regions on the pupil plane of the illumination optical system whereby a polarization direction of light in each portion on the pupil plane can be set to either of the orthogonal polarization directions (e.g., cf. Patent Literature 1).

### CITATION LIST

### Patent Literatures

Patent Literature 1: International Publication WO 2009/034109

### SUMMARY OF INVENTION

### Technical Problem

The conventional illumination optical apparatus was configured to guide each of beams through the birefringent crystal to once divide it into two beams with the orthogonal polarization directions and individually reflect the two divided beams; for this reason, the individually-settable polarization direction was limited to either of the orthogonal polarization directions. Concerning this, in applications in which, for example, in annular illumination, a distribution of polarization directions in an annular light intensity distribution is set substantially in circumferential directions or in radial directions, it is preferable to generate a distribution of various polarization states including linearly polarized light beams in at least four polarization directions. However, the conventional illumination optical apparatus failed to permit such setting of the distribution of polarization states.

In light of the above-described circumstances, it is an object of the present invention to enable an illumination target surface to be illuminated with light having a distribution of various polarization states.

### Solution to Problem

A first aspect of the present invention provides an illumination optical apparatus for illuminating an illumination target surface with light supplied from a light source. This illumination optical apparatus comprises: a separating optical system which separates the light supplied from the light source, into a first beam and a second beam in respective polarization states different from each other; a varying optical system which is arranged in an optical path of at least one of the first beam and the second beam and which varies a phase difference distribution between the first beam and the second beam; and a combining optical system which combines the first beam and the second beam between which the phase difference distribution has been varied.

A second aspect provides an illumination optical apparatus for illuminating an illumination target surface with light supplied from a light source. This illumination optical apparatus comprises: a separating optical system which separates the light supplied from the light source, into a first beam and a second beam in respective polarization states different from each other; a varying optical system which is arranged in an optical path of at least one of the first beam and the second beam and which varies a phase difference distribution between the first beam and the second beam; a combining optical system which combines the first beam and the second beam between which the phase difference distribution has been varied; and a polarization state changing element which is arranged in an optical path of a compound beam obtained by the combining optical system and which changes a polarization state of the compound beam.

A third aspect provides an exposure apparatus for illuminating a pattern with exposure light and exposing a substrate with the exposure light via the pattern and a projection optical system, the exposure apparatus comprising the illumination optical apparatus according to the aspect of the present invention and using light from the illumination optical apparatus as the exposure light.

A fourth aspect provides an optical unit for changing a polarization state of light supplied from a light source. This optical unit comprises: a separating optical system which separates the light supplied from the light source, into a first beam and a second beam in respective polarization states different from each other; a varying optical system which is arranged in an optical path of at least one of the first beam and the second beam and which varies a phase difference distribution between the first beam and the second beam; a combining optical system which combines the first beam and the second beam between which the phase difference distribution has been varied; and a polarization state changing element which is arranged in an optical path of a compound beam obtained by the combining optical system and which changes a polarization state of the compound beam.

A fifth aspect provides an illumination method for illuminating an illumination target surface with light supplied from a light source. This illumination method comprises: separating the light supplied from the light source, into a first beam and a second beam in respective polarization states different from each other; establishing a variable phase difference distribution between the first beam and the second beam; and combining the first beam and the second beam the variable phase difference distribution between which has been established.

A sixth aspect provides an illumination method for illuminating an illumination target surface with light supplied from a light source. This illumination method comprises: separating the light supplied from the light source, into a first beam and a second beam in respective polarization states different from each other; varying a phase difference distribution between the first beam and the second beam; combining the first beam and the second beam between which the phase difference distribution has been varied; and guiding a compound beam obtained by the combining optical system, through a polarization state changing element.

A seventh aspect provides an exposure method for illuminating a pattern with exposure light and exposing a substrate with the exposure light via the pattern and a projection optical system. This exposure method employs the illumination method according to the aspect of the present invention to use the light directed toward the illumination target surface, as the exposure light.

An eighth aspect provides a device manufacturing method comprising: forming a pattern of a photosensitive layer on the substrate, using the exposure method or the exposure apparatus according to the aspect of the present invention; and processing the substrate with the pattern formed thereon.

### Advantageous Effects of Invention

According to the illumination optical apparatus of the first aspect or the illumination method of the fifth aspect of the present invention, the first beam and the second beam in the mutually different polarization states with the phase difference distribution established between them are combined. The two beams after combined have a distribution of various variable polarization states, depending upon the phase difference distribution. Therefore, the illumination target surface can be illuminated with light having a distribution of various polarization states, using the two beams after combined.

According to the illumination optical apparatus of the second aspect, the optical unit of the fourth aspect, or the illumination method of the sixth aspect of the present invention, the two beams in the mutually different polarization states with the phase difference distribution established between them are combined and guided through the polarization state changing element. This allows us, for example, to obtain a variable polarization distribution with various polarization directions depending upon the phase difference distribution. Therefore, the illumination target surface can be illuminated with light having a distribution of various polarization states, using the light having been guided through the polarization state changing element.

### BRIEF DESCRIPTION OF DRAWINGS

FIG. 1 is a drawing showing a schematic configuration of an exposure apparatus as an example of embodiment.

FIG. 2A is a drawing showing an optical system including a polarizing unit 15 in FIG. 1, FIG. 2B is a drawing showing a polarization direction of incident illumination light, and FIG. 2C and FIG. 2D are drawings showing polarization states of a first beam and a second beam, respectively.

FIG. 3A is a drawing showing a light intensity distribution of annular illumination, and FIGS. 3B and 3C are drawings showing respective examples of distributions of polarization states in annular illumination.

FIG. 4A is a drawing showing a light intensity distribution of normal illumination, and FIGS. 4B and 4C are drawings showing respective examples of distributions of polarization states in normal illumination.

FIG. 5A is a drawing showing a light intensity distribution of quadrupolar illumination, and FIGS. 5B and 5C are drawings showing respective examples of distributions of polarization states in quadrupolar illumination.

FIG. 6 is a flowchart showing an example of an exposure method including an illumination method.

FIG. 7 is a drawing showing the polarizing unit in a first modification example.

FIG. 8 is a drawing showing the polarizing unit in a second modification example.

FIG. 9 is a drawing showing the polarizing unit in a third modification example.

FIG. 10A is a drawing showing the polarizing unit in a fourth modification example, and FIG. 10B is an enlarged perspective view showing a part of a variable polarizing element in FIG. 10A.

FIG. 11 is a drawing showing the polarizing unit in a fifth modification example.

FIG. 12A is a drawing showing a major part of an illumination apparatus according to another example of embodiment, and FIG. 12B is an enlarged view showing the polarizing unit in FIG. 12A.

FIG. 13 is a flowchart showing an example of steps for manufacturing electronic devices.

### DESCRIPTION OF EMBODIMENTS

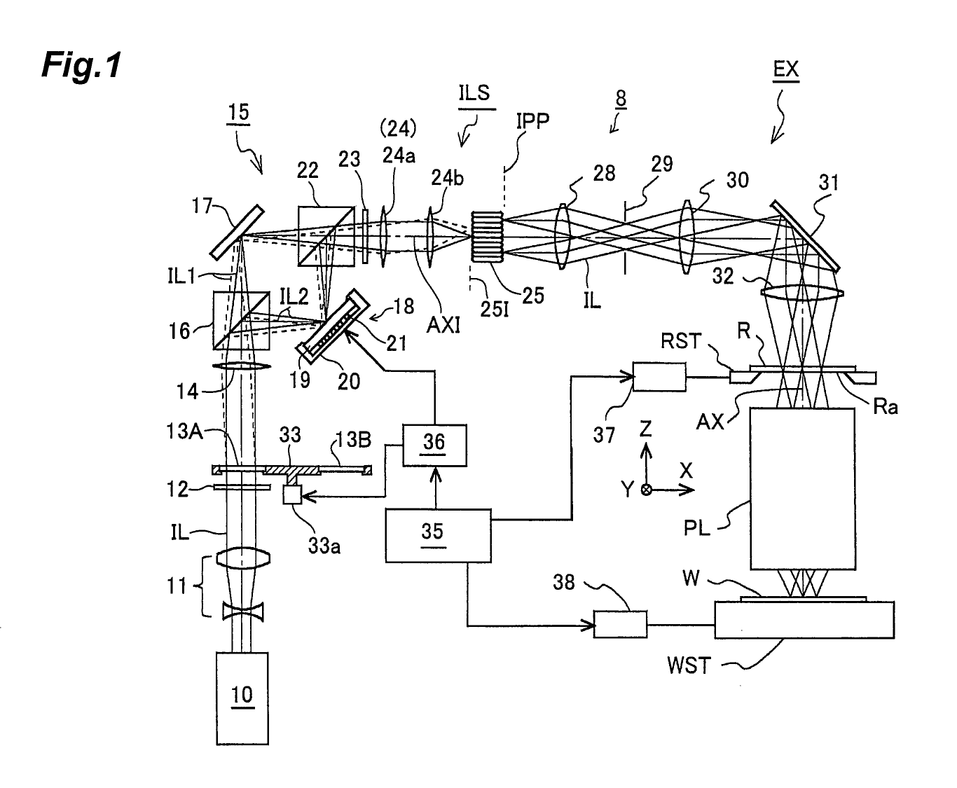

An example of the embodiment of the present invention will be described with reference to FIGS. 1, 2A-2D, 3A-3C, 4A-4C, 5A-5C, and 6.

FIG. 1 shows a schematic configuration of an exposure apparatus EX according to the present embodiment. The exposure apparatus EX is a scanning exposure type exposure apparatus (projection exposure apparatus) consisting of a scanning stepper (scanner) as an example. In FIG. 1, the exposure apparatus EX is provided with an illumination apparatus 8 which illuminates a reticle surface Ra being a pattern surface of a reticle R (mask), with illumination light for exposure (exposure light) IL. The illumination apparatus 8 is provided with a light source 10 which generates the illumination light IL, an illumination optical system ILS which illuminates the reticle surface Ra with the illumination light IL from the light source 10, and an illumination control unit 36. Furthermore, the exposure apparatus EX is provided with a reticle stage RST for moving the reticle R, a projection optical system PL for projecting an image of a pattern on the reticle R onto a surface of a wafer W (substrate), a wafer stage WST for moving the wafer W, a main control system 35 consisting of a computer for generally controlling the operation of the entire apparatus, various control systems, and so on.

The description hereinbelow will be based on such a coordinate system that the Z-axis is set in parallel with the optical axis of the projection optical system PL, the X-axis is set along a direction parallel to the plane of FIG. 1 in a plane perpendicular to the Z-axis, and the Y-axis is set along a direction perpendicular to the plane of FIG. 1. In the present embodiment, scanning directions of the reticle R and the wafer W during exposure are directions parallel to the Y-axis (Y-direction). Furthermore, the description will be based on such definition that directions of rotation around axes parallel to the X-axis, Y-axis, and Z-axis (inclination directions) are defined as θx direction, θy direction, and θz direction.

The light source 10 as an example is an ArF excimer laser light source which emits pulses of linearly polarized laser light in a narrow band at the wavelength of 193 nm and with predetermined temporal and spatial coherency. It is noted that the light source 10 applicable herein can be, for example, a KrF excimer laser light source which supplies laser light at the wavelength of 248 nm, or a harmonic generator which generates a harmonic of laser light emitted from a solid-state laser light source (YAG laser, semiconductor laser, or the like).

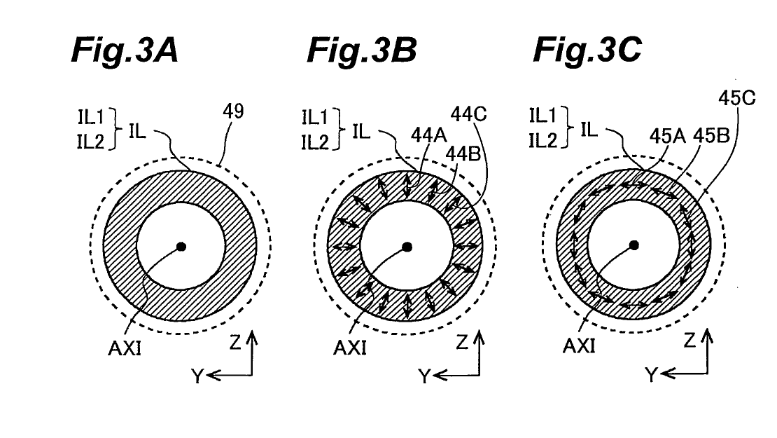

In FIG. 1, the linearly-polarized illumination light IL consisting of the laser light emitted from the light source 10 under control by an unillustrated power supply travels through a transfer optical system including a beam expander 11 and through a half wave plate 12 for adjusting the polarization direction, to enter a diffractive optical element (DEO: diffractive optical element) 13A. The diffractive optical element 13A is one for annular illumination as an example and forms a light intensity distribution in which intensity is high in an annular region, as shown in FIG. 3A, on an entrance face 25I of a below-described fly's eye lens 25. In FIG. 3A and others, the circumference 49 of a dotted line represents a region where the coherence factor (σ value) becomes 1.

In FIG. 1, the diffractive optical element 13A is supported on a turret plate 33 and other diffractive optical elements 13B . . . for different illumination conditions (normal illumination, quadrupolar illumination, dipolar illumination, etc.) are also supported on the turret plate 33. The illumination control unit 36 rotates the turret plate 33 through a drive unit 33a under control of the main control system 35 to locate a diffractive optical element appropriate for an illumination condition in the illumination optical path, thereby setting a light intensity distribution according to the illumination condition.

The illumination light IL passing through the diffractive optical element 13A (or another diffractive optical element) is incident into a polarizing unit 15. The polarizing unit 15 has an entrance optical system 14 which converts the illumination light IL from the diffractive optical element 13A into parallel light, and a first polarization beam splitter (which will be referred to hereinafter as first PBS) 16 of a prism type which splits the illumination light IL having passed through the entrance optical system 14, into a P-polarized first beam IL1 and an S-polarized second beam IL2. Furthermore, the polarizing unit 15 has a mirror 17 for reflecting the first beam IL1 transmitted by the first PBS, a deformable mirror 18 for reflecting the second beam IL2 reflected by the first PBS 16, a second polarization beam splitter (which will be referred to hereinafter as second PBS) 22 for coaxially combining the first beam IL1 reflected by the mirror 17 and the second beam IL2 reflected by the deformable mirror 18, along the optical axis AXI of the illumination optical system ILS, and a quarter wave plate 23 (polarization state varying element) which is arranged in an optical path of the coaxially combined beams IL1, IL2 and which varies the polarization state of the combined beams IL1, IL2.

In other words, the second PBS 22 is arranged so as to combine the first beam IL1 and the second beam IL2 at a position of an intersection between an axis of an extension of the optical axis of the entrance optical system 14 bent by the partial optical system (17) where the first beam IL 1 passes and an axis of an extension of the optical axis of the entrance optical system 14 bent by the partial optical system (18) where the second beam IL2 passes. The polarization separating combining surface of the second PBS may be located at the position of the intersection. Here, the optical system arranged between the first PBS and the second PBS in the optical path where the first beam IL1 passes can be referred to as first partial optical system, and the optical system arranged between the first PBS and the second PBS in the optical path where the second beam IL2 passes, as second partial optical system.

The deformable mirror 18 has a mirror 19 for reflecting the second beam IL2, a holder 20 for holding the mirror 19, and a large number of extendable drive elements 21 (e.g., piezoelectric devices) arranged in a matrix on the back surface of the mirror 19. The illumination control unit 36 controls extension amounts of the large number of drive elements 21, thereby to deform the shape of the reflecting surface of the mirror 19 within the range of wavelength level of the illumination light IL. The illumination light IL emitted from the quarter wave plate 23 in the polarizing unit 15 can be controlled to have any one of various polarization direction distributions (the details of which will be described below).

The illumination light IL emitted from the polarizing unit 15 travels through a relay optical system 24 consisting of a first lens unit 24a and a second lens unit 24b, to impinge on the entrance face 25I of the fly's eye lens 25. The relay optical system 24 keeps the reflecting surface of the mirror 19 of the deformable mirror 18 optically conjugate with the entrance face 25I. The fly's eye lens 25 is an optical element in which a large number of lens elements are arranged in nearly close contact with each other in the Z-direction and the Y-direction and an exit face of the fly's eye lens 25 is a pupil plane of the illumination optical system ILS (which will be referred to as illumination pupil plane) IPP (a plane conjugate with the exit pupil). A surface illuminant composed of a large number of secondary light sources (light source images) by wavefront division is formed on the exit face of the fly's eye lens 25 (illumination pupil plane IPP).

Since the fly's eye lens 25 is composed of the large number of optical systems arranged in parallel, a light intensity distribution on the entrance face 25I is transferred to the illumination pupil plane IPP of the exit face as it is. In other words, the entrance face 25I is a plane equivalent to the illumination pupil plane IPP and, an optional light intensity distribution and an optional polarization distribution of the illumination light IL formed on the entrance face 25I directly become a light intensity distribution and a polarization distribution on the illumination pupil plane IPP. The entrance face 25I is also substantially optically conjugate with the reticle surface. A microlens array may be used instead of the fly's eye lens 25.

The illumination light IL from the surface illuminant formed on the illumination pupil plane IPP travels via a first relay lens 28, a reticle blind (field stop) 29, a second relay lens 30, a mirror 31 for folding of optical path, and a condenser optical system 32 to illuminate an illumination region on the reticle surface Ra with a uniform illuminance distribution. The illumination optical system ILS is configured including the optical systems from the beam expander 11, half wave plate 12, diffractive optical element 13A and others, polarizing unit 15, and relay optical system 24 to the condenser optical system 32. Each optical member of the illumination optical system ILS is supported on an unillustrated frame.

Under illumination with the illumination light IL from the illumination optical system ILS, a pattern in the illumination region on the reticle R is projected through a projection optical system PL which is telecentric on both sides (or on the wafer side), at a predetermined projection magnification (e.g., ¼, ⅕, or the like) onto an exposure region in one shot area on the wafer W. The illumination pupil plane IPP is conjugate with a pupil plane of the projection optical system PL (a plane conjugate with the exit pupil). The wafer W embraces one in which a surface of a base material of silicon or the like is coated with a photoresist (photosensitive material) in a predetermined thickness.

The reticle R is sucked and held on a top surface of the reticle stage RST and the reticle stage RST is mounted on a top surface of an unillustrated reticle base (a face parallel to the XY plane) so as to be movable at a constant speed in the Y-direction and movable at least in the X-direction, the Y-direction, and the Oz direction. The two-dimensional position of the reticle stage RST is measured by an unillustrated laser interferometer and, based on information of this measurement, the main control system 35 controls the position and speed of the reticle stage RST through a drive system 37 including a linear motor or the like.

On the other hand, the wafer W is sucked and held on a top surface of the wafer stage WST through a wafer holder (not shown) and the wafer stage WST is arranged so as to be movable in the X-direction and the Y-direction on a top surface of an unillustrated wafer base (a face parallel to the XY plane) and movable at a constant speed in the Y-direction. The two-dimensional position of the wafer stage WST is measured by an unillustrated laser interferometer and, based on information of this measurement, the main control system 35 controls the position and speed of the wafer stage WST through a drive system 38 including a linear motor or the like. The apparatus is also provided with an alignment system (not shown) for implementing alignment of the reticle R and the wafer W.

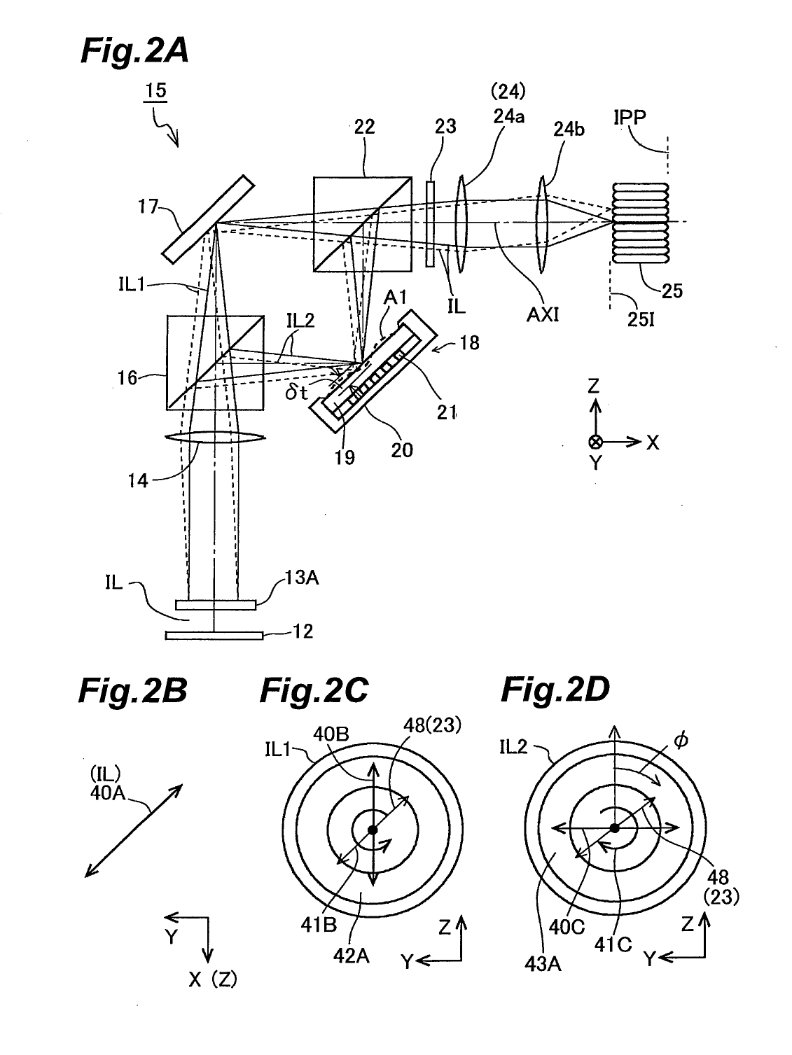

Next, the polarizing unit 15 in FIG. 1 will be described with reference to FIG. 2A. In FIG. 2A, the illumination light IL having traveled through the half wave plate 12 and the diffractive optical element 13A then travels through the entrance optical system 14 to enter the first PBS 16. The first PBS 16 splits the illumination light IL into the P-polarized first beam IL1 with the polarization direction along the X-direction and the S-polarized second beam IL2 with the polarization direction along the Y-direction. On this occasion, an intensity ratio of the linearly-polarized first beam IL 1 and second beam IL2 with their polarization directions perpendicular to each other can be adjusted by finely rotating the half wave plate 12 about the optical axis so as to finely adjust the polarization direction 40A of the illumination light IL entering the first PBS 16 (cf. FIG. 2B). In the present embodiment, it is preferable to adjust the half wave plate 12 so that the intensity ratio of the first beam IL 1 and the second beam IL2 is 1:1.

Since the polarization beam splitter usually has an angular range for separation of P-polarized light and S-polarized light being not wide, the illumination light IL incident into the first PBS 16 is the parallel light obtained through conversion by the entrance optical system 14. At the same time, the entrance optical system 14 also has a function to form the light intensity distribution to be formed on the entrance face 25I, on the reflecting surface of the mirror 19 of the deformable mirror 18. The reflecting surface of the mirror 19 is also kept conjugate with the entrance face 25I of the fly's eye lens 25 by the relay optical system 24. The first beam IL1 is reflected by the mirror 17 to travel toward the second PBS 22 and the second beam IL2 is reflected by the mirror 19 of the deformable mirror 18 to travel toward the second PBS 22.

The linearly-polarized first beam IL1 and second beam IL2 are coaxially combined along the optical axis AXI parallel to the X-axis by the second PBS 22 and are incident as illumination light IL into the quarter wave plate 23. In this case, the polarization direction 40B of the first beam IL 1 incident into the quarter wave plate 23 is the Z-direction as shown in FIG. 2C and the polarization direction 40C of the second beam IL2 incident into the quarter wave plate 23 is the Y-direction as shown in FIG. 2D. Furthermore, the direction of the fast axis (optic axis) 48 of the quarter wave plate 23 is set along a direction intersecting at 45° with the Y-axis, i.e., along a direction intersecting at 45° with the polarization directions 40B, 40C. As a result, the first beam IL 1 after passing through the quarter wave plate 23 is, for example, right-handed circularly-polarized light indicted by polarization direction 41B and the second beam IL1 after passing through the quarter wave plate 23 is, for example, left-handed circularly-polarized light indicated by polarization direction 41C.

Furthermore, the second beam IL2 incident into the quarter wave plate 23 is given a phase difference distribution from the first beam IL1 by the deformable mirror 18. As described above, since the first beam IL1 and the second beam IL2 after passing through the quarter wave plate 23 are the circularly polarized light beams in the opposite directions to each other and there are phase differences at respective positions in the radial directions and circumferential directions, the illumination light IL after passing at the respective positions is linearly polarized light directed in various directions depending upon the phase differences. In other words, polarization states in a beam section of the first beam IL1 and the second beam IL2 combined through the quarter wave plate 23 have linear polarizations directed in directions different from each other. Therefore, the polarization state of the illumination light IL impinging on the entrance face 25I of the fly's eye lens 25 is a collection of linearly polarized light beams directed in various polarization directions according to the phase difference distribution.

The process of generating the linearly polarized light beams directed in various polarization directions as described above will be explained using Jones vectors. A Jones vector is a vector consisting of polarization components in two orthogonal directions of light as an object. First, assuming that the polarization direction 40A of the incident illumination light IL shown in FIG. 2B is inclined at 45° to the Y-axis, an axis parallel to the polarization direction 40A is defined as x-axis and an axis perpendicular to the x-axis in the XY plane is defined as y-axis. At this time, a Jones vector consisting of x-axis and y-axis polarization components of the incident illumination light IL is given as in the left side of the following formula (1).

$$( \begin{matrix}1 \\ 0\end{matrix} ) = ( \begin{matrix}1 / 2 \\ 1 / 2\end{matrix} ) + ( \begin{matrix}1 / 2 \\ - 1 / 2\end{matrix} ) \qquad ( 1 )$$

In this case, Jones vectors of the first beam IL 1 and the second beam IL2 split by the first PBS 16 are the first vector and the second vector, respectively, in the right side of formula (1). When the second beam IL2 is then given the phase difference δ by the deformable mirror 18, the Jones vector of the second beam IL2 turns into the one represented by the right side of formula (2).

$$( \begin{matrix}1 / 2 \\ - 1 / 2\end{matrix} ) ⇒ ( \begin{matrix}1 / 2 exp ( i δ ) \\ - 1 / 2 exp ( i δ )\end{matrix} ) \qquad ( 2 )$$

When the first beam IL1 and the second beam IL2 are then combined by the second PBS 22, a Jones vector of the compound illumination light IL is given by the following formula.

$$( \begin{matrix}1 / 2 \\ 1 / 2\end{matrix} ) + ( \begin{matrix}1 / 2 exp ( i δ ) \\ - 1 / 2 exp ( i δ )\end{matrix} ) = ( \begin{matrix}cos ( \frac{δ}{2} ) exp ( i \frac{δ}{2} ) \\ - sin ( \frac{δ}{2} ) exp ( i \frac{δ + π}{2} )\end{matrix} ) \qquad ( 3 )$$

The action of the quarter wave plate 23 can be expressed by a Jones matrix as below.

$$( \begin{matrix}1 & 0 \\ 0 & exp ( i \frac{π}{2} )\end{matrix} ) \qquad ( 4 )$$

The aforementioned illumination light IL after combined is guided through the quarter wave plate 23, obtaining the below Jones vector.

$$( \begin{matrix}cos ( \frac{δ}{2} ) exp ( i \frac{δ}{2} ) \\ sin ( \frac{δ}{2} ) exp ( i \frac{δ}{2} )\end{matrix} ) \qquad ( 5 )$$

Namely, it is understood that the finally-obtained illumination light IL is linearly polarized light and that the polarization direction of the linearly polarized light rotates depending upon the phase difference δ given by the deformable mirror 18. A necessary condition for allowing the polarization direction to be set to any direction is that the angle (δ/2) of the polarization direction is within ±90° (from 0 to 180°).

For meeting this condition, when an average angle of incidence of the second beam 1L2 to the mirror 19 in FIG. 2A is assumed to be 45°, a displacement δt in the normal direction at each point on the reflecting surface of the mirror 19 needs to be within the following range using the wavelength λ of the illumination light IL (i.e., ±180° in terms of phase).

−λ/2≦2^{1/2}·δt<λ/2 (6)

In FIG. 2A, when the reflecting surface of the mirror 19 is deformed as indicated by a face A1 of a dotted line, the phase of the reflected light changes and the direction of reflection also changes depending upon a derivative value of deformation amount (change amount of local inclination). However, since in the present embodiment the reflecting surface of the mirror 19 and the entrance face 25I of the fly's eye lens 25 are arranged as conjugate with each other, there is no change in position where the illumination light IL arrives on the entrance face 25I and thus a desired polarization distribution can be readily obtained.

Specifically, let us assume that the intensity distribution of the illumination light IL on the entrance face 25I is a distribution in which intensity is high in an annular region, as shown in FIG. 3A. At this time, intensity distributions on the entrance face 25I of the first beam IL 1 and the second beam IL2 are also distributions in which intensity is high in an annular region 42A in FIG. 2C and an annular region 43A in FIG. 2D, respectively. Then, the phase difference between the beams IL1, IL2 is set to gradually change in the circumferential direction φ in the region 43A, by the deformable mirror 18. By this setting, as an example, the polarization state of the illumination light IL on the entrance face 25I can be set to be a collection of linearly polarized light beams polarized in radial directions 44A, 44B, 44C, . . . with respect to the optical axis AXI in the annular region, as shown in FIG. 3B. As another example, the polarization state of the illumination light IL on the entrance face 25I can be set to be a collection of linearly polarized light beams polarized in circumferential directions 45A, 45B, 45C, . . . with respect to the optical axis AXI in the annular region, as shown in FIG. 3C. Besides them, the polarization state in the annular region can be set to an optional polarization direction distribution.

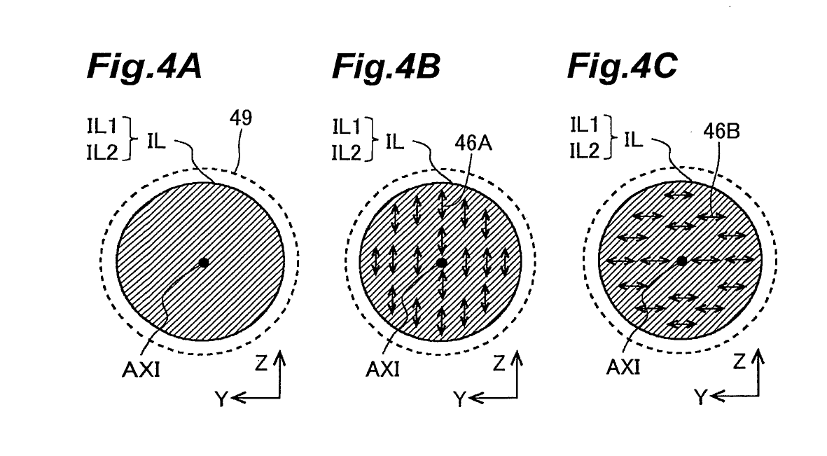

When the diffractive optical element 13B is set in the illumination optical path in FIG. 1, the light intensity distribution on the entrance face 25I of the fly's eye lens 25 is a distribution in which intensity is high in a circular region as shown in FIG. 4A. In this case, when the phase difference distribution between the beams IL1, IL2 is controlled by the deformable mirror 18, the polarization state of the illumination light IL on the entrance face 25I can be set to linear polarization in a direction 46A parallel to the Z-axis shown in FIG. 4B, to linear polarization in a direction 46B parallel to the Y-axis shown in FIG. 4C, or to any other polarization direction distribution. For setting the polarization directions on the entire surface to the Z-direction or the Y-direction as shown in FIG. 4B or in FIG. 4C, the half wave plate 12 may be rotated in FIG. 2A so as to set the polarization direction of the illumination light IL incident into the polarizing unit 15 to the X-direction or the Y-direction. Furthermore, by establishing a random phase difference distribution by the deformable mirror 18, it is also possible to set a substantially unpolarized state.

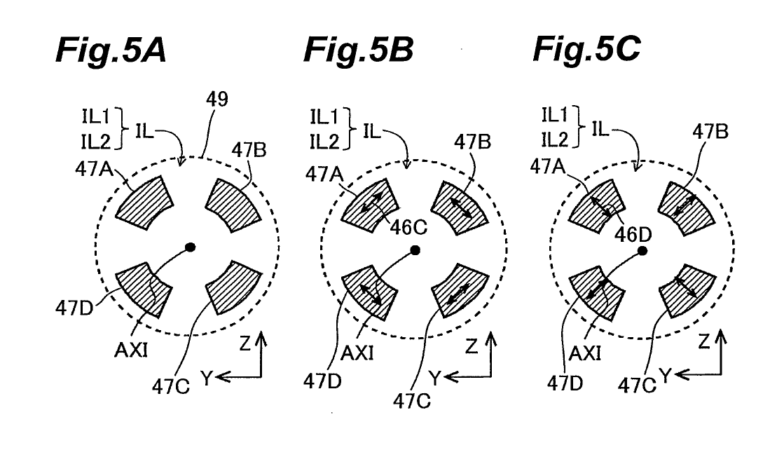

When quadrupolar illumination is selected as the illumination condition, the light intensity distribution on the entrance face 25I of the fly's eye lens 25 is a distribution in which intensity is high in four regions 47A-47D as shown in FIG. 5A (or regions resulting from 90° rotation of the foregoing regions). In this case as well, when the phase difference distribution between the beams IL1, IL2 is controlled by the deformable mirror 18, the polarization state of the illumination light IL on the entrance face 25I can be set to linear polarization in circumferential directions 46C shown in FIG. 5B, to linear polarization in radial directions 46D shown in FIG. 5C, or to any other polarization direction distribution.

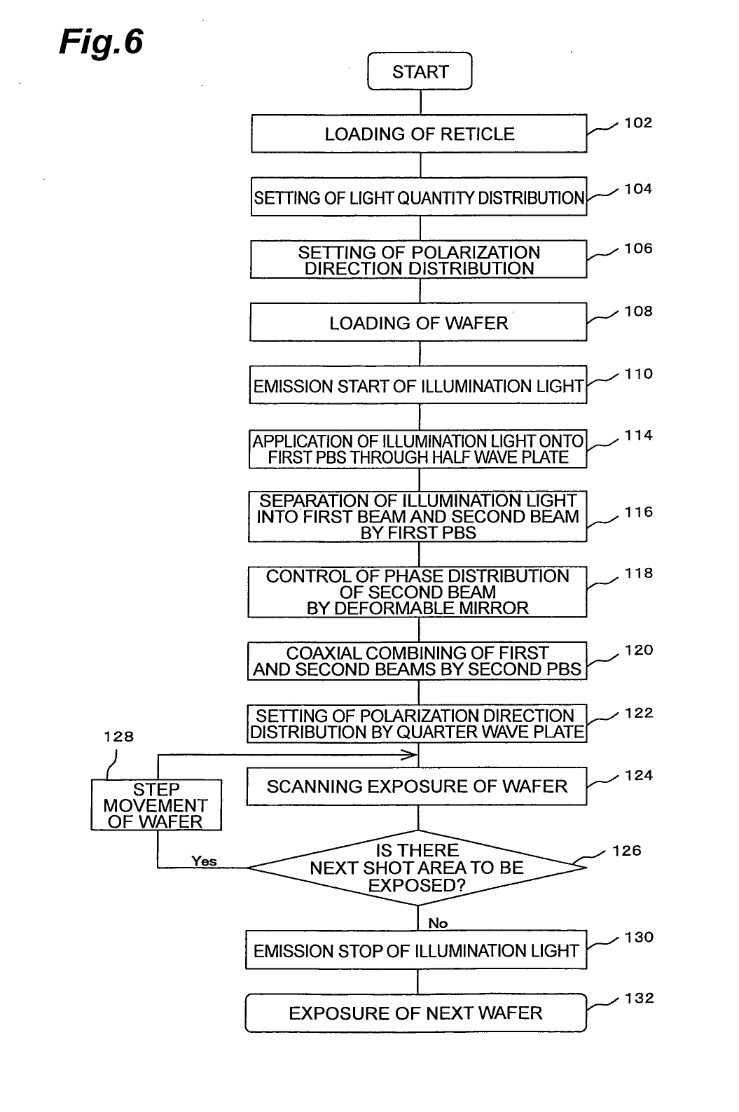

Next, an example of an exposure method including an illumination method by the exposure apparatus EX of the present embodiment will be described with reference to the flowchart of FIG. 6. This operation is controlled by the main control system 35.

First, in step 102 in FIG. 6, the reticle R is loaded on the reticle stage RST in FIG. 1. In next step 104, the main control system 35 reads out information (illumination condition) on a target distribution of light intensity distribution and a target distribution of polarization state on the illumination pupil plane IPP, for example, from an exposure data file, in accordance with a pattern on the reticle R as an exposure target. Then, one of the diffractive optical elements 13A, 13B, etc. is located in the illumination optical path through the illumination control unit 36, to set the light intensity distribution (light quantity distribution) on the entrance face 25I and, in turn, on the illumination pupil plane IPP. In next step 106, the shape of the reflecting surface of the mirror 19 of the deformable mirror 18 is controlled through the illumination control unit 36 in accordance with the target polarization state distribution, to set the phase difference distribution between the beams IL1, IL2. This step results in setting a distribution of polarization directions at respective positions on the entrance face 25I and, in turn, on the illumination pupil plane IPP.

In next step 108, the wafer W coated with the photoresist is loaded on the wafer stage WST. Then, emission of the illumination light IL from the light source 10 is started (step 110) and, thereafter, the illumination light IL is applied to the first PBS 16 of the polarizing unit 15 through the half wave plate 12 (step 114). Next, the illumination light IL is split (or separated) into the first beam IL1 and the second beam IL2 by the first PBS 16 (step 116). Then, the phase distribution of the second beam IL2 is controlled by the deformable mirror 18, thereby to control the phase difference distribution between the beams IL1, IL2 (step 118). Thereafter, the beams IL 1 and IL2 are coaxially combined by the second PBS 22 (step 120) and the compound illumination light IL is guided through the quarter wave plate 23 whereby the polarization direction distribution of the illumination light IL is set to the target distribution (step 122). Irradiation of the illumination light IL onto the wafer W is controlled by opening/closing of a variable blind in the reticle blind 29 in FIG. 1.

In next step 124, while under illumination with the illumination light IL a part of one shot area on the wafer W is exposed with an image of a part of the pattern on the reticle R formed by the projection optical system PL, the reticle R and the wafer W are moved in synchronism at a speed ratio equal to a projection magnification in the Y-direction through the reticle state RST and the wafer stage WST, thereby implementing scanning exposure of the shot area on the wafer W. When there is an unexposed shot area in next step 126, step 128 is carried out to stepwise move the wafer W to the scan start position through the wafer stage WST and in next step 124 the scanning exposure is executed in the next shot area. In this manner, the exposure is carried out for each of the shot areas on the wafer W by the step-and-scan method.

When there is no unexposed shot area in step 126, the emission of the illumination light IL is stopped in step 130 and the exposure on a next wafer is carried out in step 132. According to the present embodiment, as described above, all the shot areas on the wafer W can be exposed with the image of the pattern on the reticle R in high resolution in an optional target light intensity distribution and an optional target polarization distribution.

As described above, the illumination apparatus 8 of the present embodiment is provided with the illumination optical system ILS and the illumination apparatus 8 illuminates the reticle surface Ra with the illumination light IL. Furthermore, the illumination optical system ILS has the polarizing unit 15. Then, the polarizing unit 15 is the optical system for changing the polarization state of the illumination light IL supplied from the light source 10, which is provided with the first PBS 16 for separating the illumination light IL into the first beam IL 1 and the second beam IL2 with the polarization directions orthogonal to each other (step 116), the deformable mirror 18 which is disposed in the optical path of the second beam IL2 to establish the variable phase difference distribution between the beams IL1, IL2 (step 118), and the second PBS 22 for coaxially combining the beams IL1, IL2 with the variable phase difference distribution established between them (step 120). Furthermore, the polarizing unit 15 is provided with the quarter wave plate 23 arranged in the optical path of the illumination light IL obtained by combining the beams IL1, IL2. When the beams IL1, IL2 combined by the second PBS 22 (illumination light IL) are guided through the quarter wave plate 23, the distribution of linear polarizations with respective polarization directions depending upon the phase difference distribution is generated from the two oppositely-rotating circularly-polarized light beams with the variable phase difference distribution established between them (step 122).

According to the present embodiment, the beams IL1, IL2 with the respective polarization directions orthogonal to each other between which the variable phase difference distribution has been established are coaxially combined. The beam obtained by combining the two beams IL1, IL2 is guided through the quarter wave plate 23, thereby to obtain the two oppositely-rotating circularly-polarized light beams with the variable phase difference distribution established between them. The polarization state of the illumination light IL resulting from combining of the two circularly polarized light beams is a distribution of linear polarizations with various polarization directions according to the variable phase difference distribution. Therefore, the reticle surface Ra can be illuminated with the light having the distribution of various polarization directions.

It is noted that the second PBS 22 does not always have to coaxially combine the beams IL1, IL2. If an optical system for separating the incident light into two oppositely-rotating circularly-polarized light beams is used instead of the first PBS 16, there is no need for use of the quarter wave plate 23.

Instead of the quarter wave plate 23, it is also possible to use an element for varying the polarization state, such as a ½, ⅛, or other wave plate, a polarizer, or an analyzer, or to vary the polarization state by a combination of these elements.

The exposure apparatus EX of the present embodiment is the exposure apparatus for illuminating the reticle R with the illumination light IL for exposure and exposing the wafer W with the illumination light IL via the pattern and the projection optical system PL, which is provided with the illumination apparatus 8 and which uses the illumination light from the illumination apparatus 8 as the illumination light IL. Since this exposure apparatus EX can illuminate the pattern with the illumination light IL having the optimal polarization direction distribution according to the pattern on the reticle R, the wafer W can be exposed with an image of any one of various patterns in high resolution.

The present embodiment can be modified as described below.

First, a spatial light modulator (SLM: spatial light modulator) of a movable multi-mirror system having a large number of microscopic mirror elements a position in the normal direction of a reflecting face of each of which is variable may be used instead of the deformable mirror 18. Such spatial light modulator of the phase modulation type to be used herein can be, for example, the one disclosed in Reference Literature 1 “Yijian Chen et al., “Design and fabrication of tilting and piston micromirrors for maskless lithography,” Proc. of SPIE (U.S.A.) Vol. 5751, pp. 1023-1037 (2005)” or the one disclosed in Reference Literature 2 “D. Lopez et al., “Two-dimensional MEMS array for maskless lithography and wavefront modulation,” Proc. of SHE (U.S.A.) Vol. 6589, 65890S (2007).”

The arrangement of the polarizing unit 15 in the illumination optical system ILS does not have to be limited to the arrangement in FIG. 1 but it can be arranged at any position necessary for an optional polarization distribution. For example, the polarizing unit 15 may be arranged in front of (upstream of) the diffractive optical element 13A (or another diffractive optical element) in FIG. 1. This arrangement allows the polarization directions of the light incident into the diffractive optical element 13A or the like to be made different depending upon positions and, when beams in the respective polarization directions are diffracted to optional positions on the entrance face 25I (and, in turn, on the illumination pupil plane IPP), the exit pupil of the illumination optical system ILS can be formed with an optional polarization distribution.

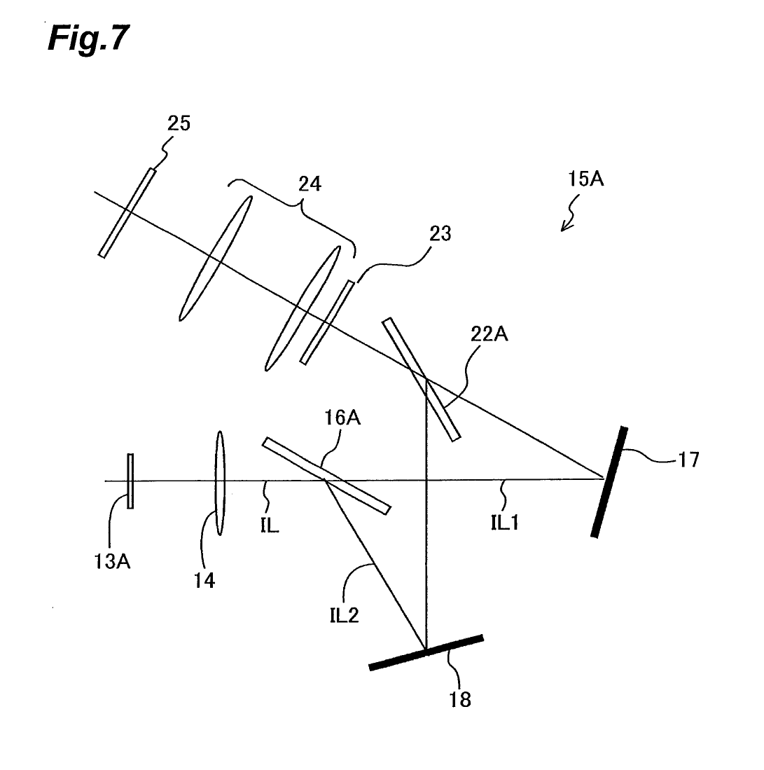

Furthermore, a polarizing unit 15A in a first modification example shown in FIG. 7 may be used instead of the polarizing unit 15 in FIG. 1. In FIG. 7 and other figures to which reference will be made hereinafter, portions corresponding to those in FIG. 1 will be denoted by the same reference signs, without detailed description thereof. In FIG. 7, the polarizing unit 15A is a unit using polarization beam splitters (each one will be referred to hereinafter as PBS) 16A and 22A each of which consists of a plane-parallel plate coated with a polarization beam splitter film, instead of the first PBS 16 and the second PBS 22 of the prism type in FIG. 1, and the configuration other than it is the same as that of the polarizing unit 15. Since the PBSs 16A, 22A of the plane-parallel plates are inexpensive and have high endurance, the polarizing unit 15A can be configured at low cost and with wider maintenance intervals.

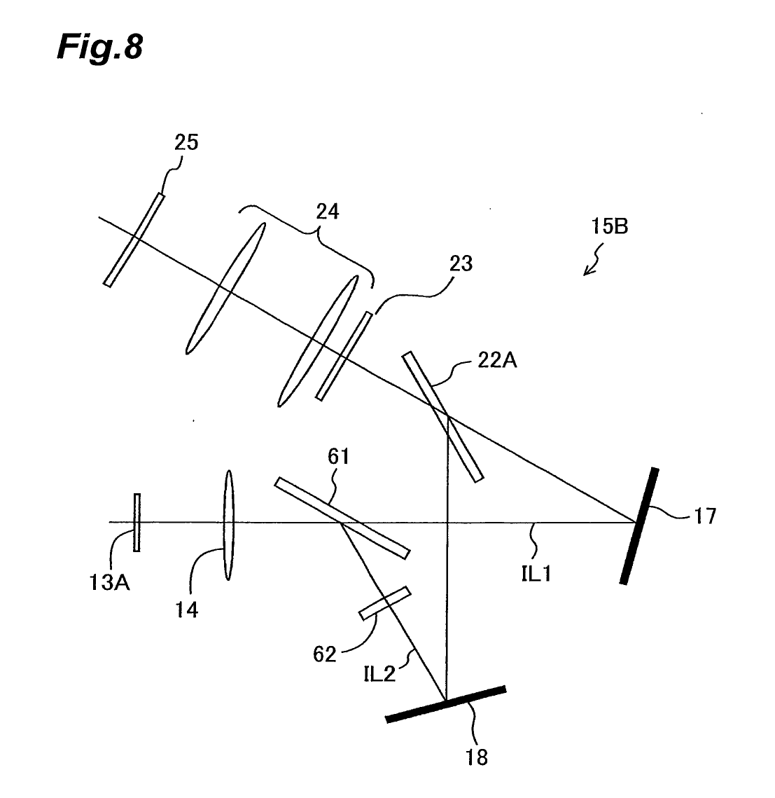

A polarizing unit 15B in a second modification example shown in FIG. 8 may be used instead of the polarizing unit 15A in FIG. 7. In FIG. 8, the polarizing unit 15B is a unit obtained by replacing the PBS 16A in FIG. 7 with an ordinary half mirror 61 and a half wave plate 62. In the polarizing unit 15B, the P-polarized illumination light IL from the entrance optical system 14 is divided into the first beam IL1 and the second beam IL2 by the half mirror 61 and the first beam IL1 is reflected by the mirror 17 to be incident as P-polarized light into the PBS 22A. On the other hand, the second beam IL2 is converted into S-polarized light by the half wave plate 62 and thereafter is reflected by the deformable mirror 18 to enter the PBS 22A to be coaxially combined with the first beam IL1, Since this configuration needs only one PBS, it is realized at lower cost.

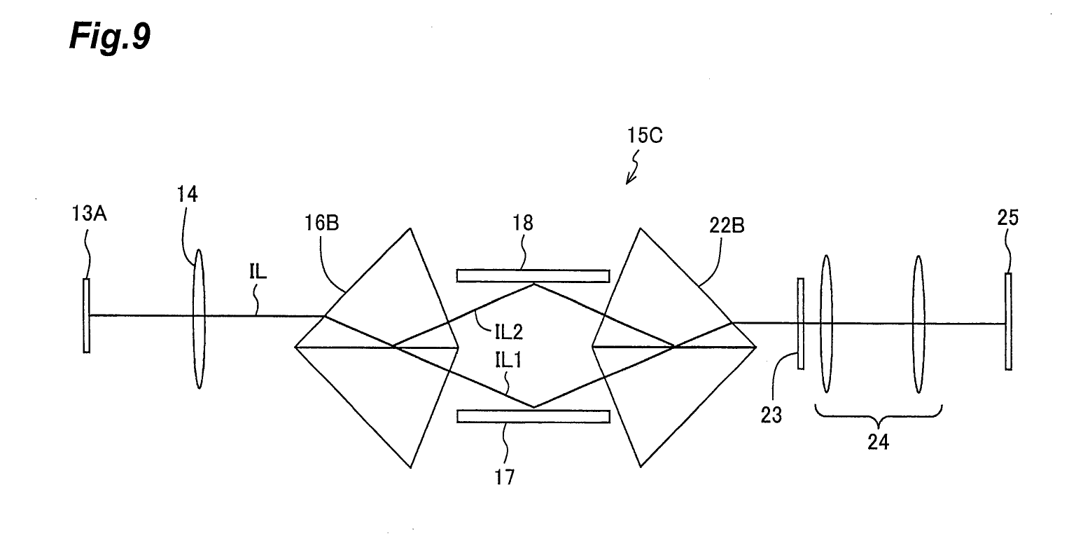

Furthermore, a polarizing unit 15C in a third modification example shown in FIG. 9 may be used instead of the polarizing unit 15 in FIG. 1. In FIG. 9, the polarizing unit 15C has a first PBS 16B of a rhombic sectional shape for separating the illumination light IL from the entrance optical system 14 into the first beam IL1 and the second beam IL2 with the orthogonal polarization directions, the mirror 17 and the deformable mirror 18 for reflecting the beams IL1, IL2, respectively, and a second PBS 22B of a rhombic sectional shape for coaxially combining the reflected beams IL1, IL2. The configuration other than it is the same as that of the polarizing unit 15. Since this polarizing unit 15C does not require the mirror for folding of optical path and thus allows the entrance axis and the exit axis of the illumination light IL to be arranged on the same axis, manufacture (assembly•adjustment) thereof is easy.

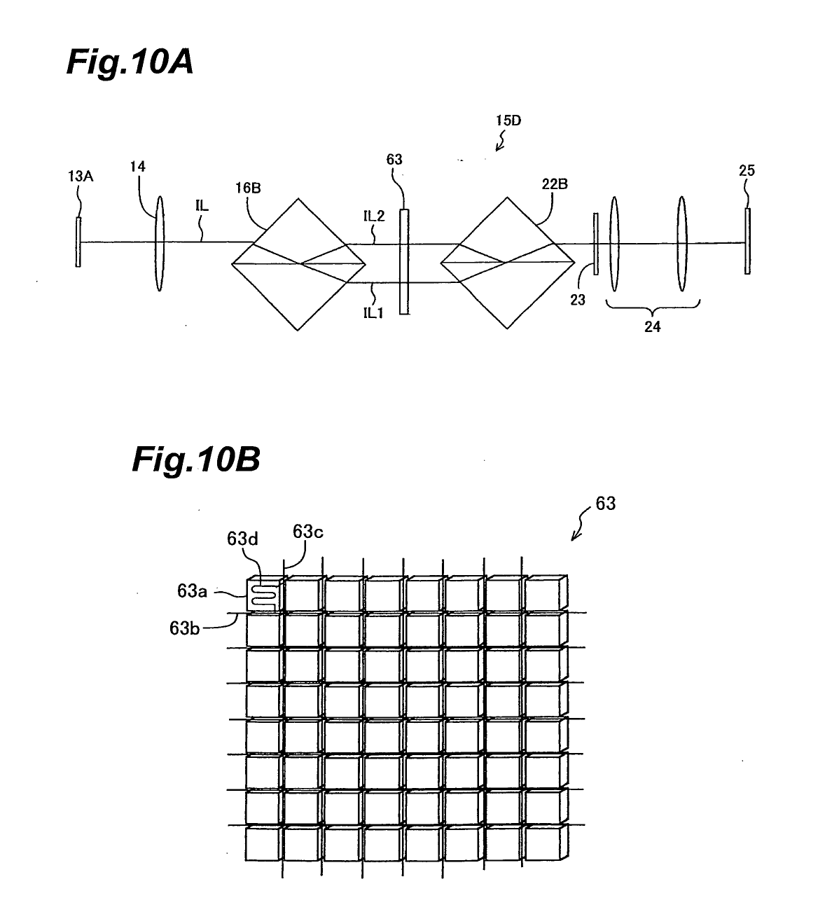

In FIG. 1 the reflection type deformable mirror 18 was used as the optical system for establishing the optional phase difference distribution, but a transmission type optical system may be used, as shown in a polarizing unit 15D in a fourth modification example in FIG. 10A. In FIG. 10A, a transmission-type variable polarizing element 63 is arranged instead of the mirror 17 and the deformable mirror 18 in FIG. 9 and the beams IL1, IL2 emitted from the first PBS 16B are incident in parallel through the variable polarizing element 63 into the second PBS 22B to be coaxially combined.

The variable polarizing element 63, as shown in FIG. 10B, has a glass plate partitioned into a large number of microscopic segments 63a, heating elements 63d provided for the respective segments 63a so as to little affect the beams, and horizontal signal lines 63b and vertical signal lines 63c for supplying an electric current to the heating element 63d of an optional segment 63a. In this case, only a specific segment 63a is heated by the heating element 63d to change the refractive index of the specific segment 63a, whereby an optional phase distribution can be established in the wavefront of the beam transmitted by the variable polarizing element 63. Therefore, when the variable phase difference distribution is established between the beams IL1, IL2 by the variable polarizing element 63 in FIG. 10A, the polarization distribution of the illumination light transmitted by the quarter wave plate 23 can be set to an optional polarization direction distribution.

The transmission-type variable polarizing element 63 to be employed herein may be a system for heating a specific segment 63a with infrared light from the outside to change the refractive index thereof, instead of the system for heating the specific segment 63a by the heating element 63d.

Furthermore, instead of the glass plate, a plurality of elements having the electro-optic effect may be used so that an electric field or a magnetic field is applied to a specific element to change the refractive index of the element (or to change the refractive index distribution of all the elements).

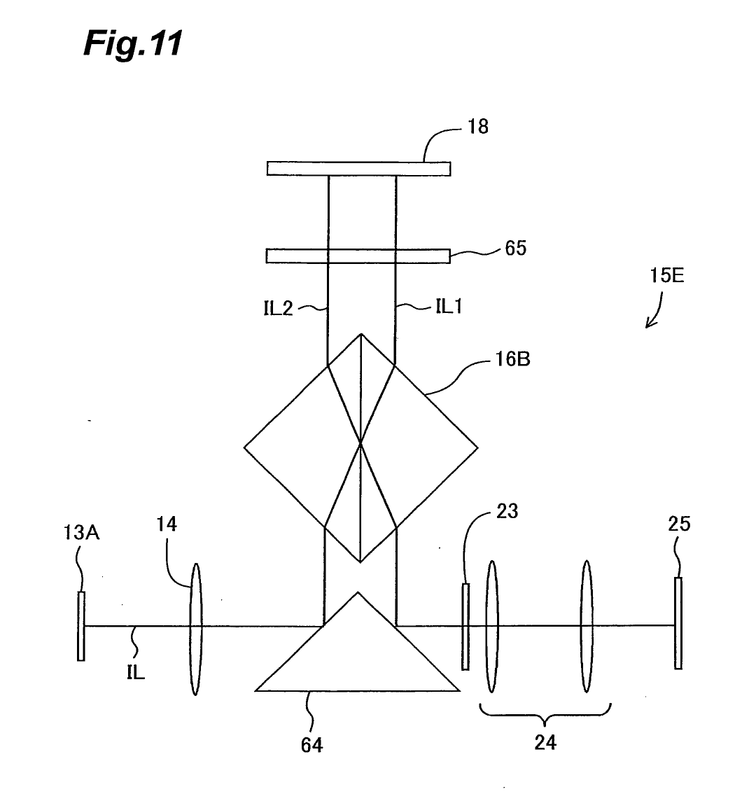

Furthermore, a polarizing unit 15E in a fifth modification example shown in FIG. 11 may also be used instead of the polarizing unit 15 in FIG. 1. In FIG. 11, the polarizing unit 15E has a mirror 64 having two reflecting faces for reflecting the illumination light IL from the entrance optical system 14, the PBS 16B for separating the reflected illumination light IL into the P-polarized first beam IL1 and the S-polarized second beam IL2, a quarter wave plate 65 for converting the separated beams IL1, IL2 into oppositely-rotating circularly-polarized light beams, and the deformable mirror 18 for establishing the variable phase difference distribution between the circularly polarized light beams IL1, IL2 and reflecting the beams. In this case, since the beams IL1, 1L2 reflected by the deformable mirror 18 turn into S-polarized light and P-polarized light, respectively, through the quarter wave plate 65, they are coaxially combined by the PBS 16B to be reflected by the mirror 64. The reflected beams travel through the quarter wave plate 23 and the relay optical system 24 to enter the fly's eye lens 25. This polarizing unit 15E requires only one PBS 16B and can establish the optional phase difference distribution accurately between the beams IL1, IL2.

In the above embodiment and modification examples thereof (the same will apply hereinafter), a Wollaston prism may be used instead of the polarization beam splitter or the mirror with the polarization beam splitter film.

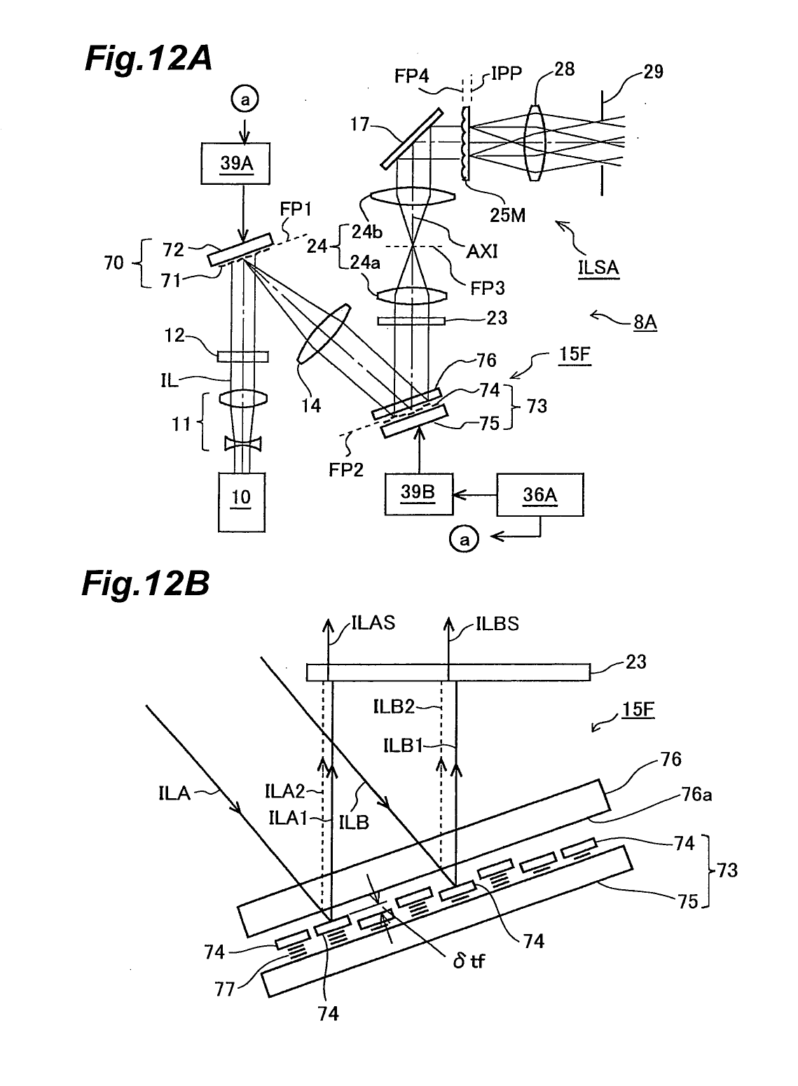

Next, another example of the embodiment will be described with reference to FIGS. 12A and 12B. In FIG. 12A, portions corresponding to those in FIG. 1 will be denoted by the same reference signs, without detailed description thereof.

FIG. 12A shows the major part of an illumination apparatus 8A in the exposure apparatus of the present embodiment. The illumination apparatus 8A is provided with the light source 10, an illumination optical system ILSA for illuminating the illumination target surface (reticle surface Ra in FIG. 1) with the illumination light in an optional polarization state obtained from the linearly-polarized illumination light IL supplied from the light source 10, and an illumination control unit 36A. The configuration other than it is the same as that of the exposure apparatus EX in FIG. 1.

In FIG. 12A, the linearly-polarized illumination light IL of the laser light emitted from the light source 10 travels via the beam expander 11 and the half wave plate 12 to enter an array of a large number of microscopic mirror elements 71 which are arranged on a top surface of a base member 72 in a first spatial light modulator (SLM) 70 of the movable multi-mirror system and in each of which angles of inclination about two orthogonal axes are variable. The first spatial light modulator 70 to be used herein can be, for example, the one disclosed in U.S. Pat. No. 7,095,546 or the one disclosed in U.S. Pat. Published Application No. 2005/0095749. A modulation control unit 39A controls the angles of inclination about the two axes of each mirror element 71 in the spatial light modulator 70 in accordance with the illumination condition instructed by the illumination control unit 36A, whereby the light quantity distribution on the illumination pupil plane IPP can be set to any distribution, e.g., a circular region in a variable size, an annular region, or a multi-pole (two-pole or four-pole or the like) region.

The illumination light IL reflected by the array of mirror elements 71 in the spatial light modulator 70 is incident into the polarizing unit 15F. The polarizing unit 15F has the entrance optical system 14 for converting the illumination light IL from the spatial light modulator 70 into parallel light, a polarization beam splitter (PBS hereinafter) 76 of a flat plate shape for splitting the illumination light IL having traveled through the entrance optical system 14, into the P-polarized first beam and the S-polarized second beam, a second spatial light modulator (SLM) 73 of the phase modulation type for reflecting the first beam transmitted by the PBS 76, and the quarter wave plate 23 arranged in the optical path of the compound beam along the optical axis AXI obtained by combining the second beam reflected by the PBS 76 and the first beam reflected by the spatial light modulator 73 and transmitted by the PBS 76.

As shown in FIG. 12B, the second spatial light modulator 73 is configured so that a two-dimensional array of a large number of microscopic mirror elements 74 are supported on a surface of a base member 75 through respective drive units 77 so as to make variable the position of each element in the normal direction on the surface. A PBS film 76a of the PBS 76 is arranged in the vicinity of the array of mirror elements 74 in the spatial light modulator 73. In this case, when δtf represents a displacement of a reflecting face of each mirror element 74 from a predetermined reference plane in the normal direction, a change amount of the phase of the first beam reflected by the mirror element 74 is proportional to the displacement δtf. The change amount of the phase is, for example, within the range of ±180°. Under control from the illumination control unit 36A, the modulation control unit 39B controls change amounts of phases of beams reflected by the respective mirror elements 74 through the respective drive units 77. The phase modulation type spatial light modulator 74 to be used herein can be, for example, the one disclosed in the aforementioned Reference Literature 1 or Reference Literature 2.

The illumination light IL emitted from the polarizing unit 15F travels via the relay optical system 24 and the mirror 17 to impinge on an entrance face FP4 of a microlens array 25M. A surface illuminant composed of a large number of secondary light sources (light source images) by wavefront division is formed on an exit face (illumination pupil plane IPP) of the microlens array 25M. The entrance face FP4 is equivalent to the illumination pupil plane IPP. The relay optical system 24 keeps an average reflecting surface FP2 of the array of mirror elements 74 in the second spatial light modulator 73 substantially optically conjugate with the entrance face FP4. The entrance optical system 14 keeps the average reflecting surface FP1 of the array of mirror elements 71 in the first spatial light modulator 70 substantially optically in a Fourier transform relation with the reflecting surface FP2 of the second spatial light modulator 73. Furthermore, a plane FP3 substantially optically conjugate with the reflecting surface FP1 of the first spatial light modulator 70 is formed between the lens units 24a, 24b of the relay optical system 24. The illumination optical system ILSA is configured including the optical systems from the beam expander 11, half wave plate 12, first spatial light modulator 70, and polarizing unit 15 to the microlens array 25M and the optical systems from the first relay lens 28 to the condenser optical system 32 in FIG. 1.

In the present embodiment, when attention is given to two illumination light beams ILA, ILB incident into the PBS 76, as shown in FIG. 12B, S-polarized second beams ILA2, ILB2 of the illumination light beams ILA, ILB are reflected by the PBS film 76a of the PBS 76 to travel toward the quarter wave plate 23. On the other hand, P-polarized first beams ILA1, ILB1 of the illumination light beams ILA, ILB are transmitted by the PBS 76, reflected by the corresponding mirror elements 74 in the spatial light modulator 73, and then transmitted by the PBS 76 toward the quarter wave plate 23. In this case, optional phase differences different from each other can be established between the beams ILA1, ILA2 and between the beams ILB 1, ILB2 with the respective polarization directions orthogonal to each other, depending upon the displacements δtf of the mirror elements 74. Therefore, when compound beams ILAS, ILBS from the beams ILA1, ILA2 and from the beams ILB1, ILB2 pass through the quarter wave plate 23, each of the beams ILAS, ILBS becomes linearly polarized light polarized in a direction depending upon the phase difference established by the spatial light modulator 73, as in the embodiment of FIG. 1. Since the reflecting face FP2 of the spatial light modulator 73 is substantially conjugate with the entrance face FP4 equivalent to the illumination pupil plane IPP, the distribution of polarization directions of the illumination light IL on the illumination pupil plane IPP can be readily controlled to any distribution by controlling the displacements of the respective mirror elements 74 independently of each other.

In the above embodiment, the polarizing unit 15F is located downstream of the first spatial light modulator 70. However, the polarizing unit 15F may be located upstream of the spatial light modulator 70.

The above embodiment uses the fly's eye lens 25 or the like which is a wavefront division type integrator in FIG. 1, as the optical integrator. However, it is also possible to use a rod type integrator as an internal reflection type optical integrator, as the optical integrator.

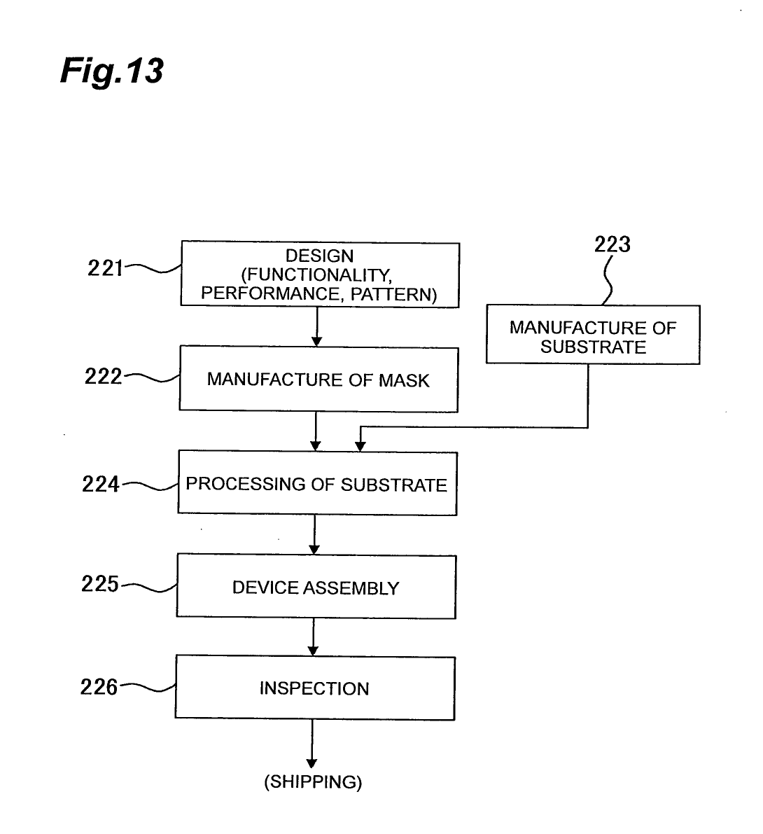

In manufacture of electronic devices (micro devices) such as semiconductor devices using the exposure apparatus EX or the exposure method in the above embodiment, the electronic devices are manufactured, as shown in FIG. 13, through step 221 to perform design of functionality and performance of devices, step 222 to manufacture a mask (reticle) based on the design step, step 223 to manufacture a substrate (wafer) as a base material of devices, substrate processing step 224 including a step of exposing the substrate with a pattern of the mask by the exposure apparatus EX or the exposure method in the aforementioned embodiment, a step of developing the exposed substrate, and heating (curing) and etching steps of the developed substrate, device assembly step (including processing processes such as dicing step, bonding step, and packaging step) 225, inspection step 226, and so on.

In other words, the above device manufacturing method includes the step of exposing the substrate (wafer W) through the pattern of the mask, using the exposure apparatus EX or the exposure method in the above embodiment, and the step of processing the exposed substrate (i.e., the development step of developing the resist on the substrate to form a mask layer corresponding to the pattern of the mask on the surface of the substrate, and the processing step of processing (heating and etching or the like) the surface of the substrate through the mask layer).

Since this device manufacturing method allows the polarization state of the illumination light (exposure light) to be readily optimized according to the pattern on the mask, the electronic devices can be manufactured with high accuracy.

It is noted that the present invention can also be applied to the liquid immersion type exposure apparatuses, for example, as disclosed in U.S. Pat. Published Application No. 2007/242247 or European Patent Application Publication EP 1420298. Furthermore, the present invention is also applicable to the illumination optical apparatuses not using the condenser optical system. Furthermore, the present invention can also be applied to the exposure apparatus of the proximity method or the like not using the projection optical system.

The present invention is not limited to the application to the processes for manufacturing the semiconductor devices, but can also be generally applied, for example, to processes for manufacturing the liquid crystal display devices, plasma displays, etc. and to processes for manufacturing various devices (electronic devices) such as imaging devices (CMOS type, CCD, etc.), micro machines, MEMS (Microelectromechanical Systems: microscopic electro-mechanical systems), thin film magnetic heads, and DNA chips.

As described above, the present invention, which is not limited to the above-described embodiments, can be realized in a variety of configurations without departing from the spirit and scope of the present invention.

The disclosures in the aforementioned Publications, International Publications, U.S. patents, or U.S. Pat. Published applications described in the present specification are incorporated herein as part of the description of the present specification. The entire disclosure of U.S. Provisional Patent Application No. 61/535,654 filed on Sep. 16, 2011 including the description, the scope of claims, the drawings, and the abstract is incorporated herein by reference in its entirety.

### REFERENCE SIGNS LIST

EX exposure apparatus, ILS illumination optical system, R reticle, PL projection optical system, W wafer, 8 illumination apparatus, 10 light source, 12 half wave plate, 13A and 13B diffractive optical elements (DOEs), 15 and 15A-15E polarizing units, 16 and 22 PBSs (polarization beam splitters), 18 deformable mirror, 23 quarter wave plate, 24 relay optical system, 25 fly's eye lens, and 36 illumination control unit.

1. An illumination optical apparatus for illuminating an illumination target surface with light supplied from a light source, the illumination optical apparatus comprising:
a separating optical system which separates the light supplied from the light source, into a first beam and a second beam in respective polarization states different from each other;
a varying optical system which is arranged in an optical path of at least one of the first beam and the second beam and which varies a phase difference distribution between the first beam and the second beam; and
a combining optical system which combines the first beam and the second beam between which the phase difference distribution has been varied.

2. The illumination optical apparatus according to claim 1, comprising: a polarization state changing element which is arranged in an optical path of a compound beam obtained by the combining optical system and which changes a polarization state of the compound beam.

3. An illumination optical apparatus for illuminating an illumination target surface with light supplied from a light source, the illumination optical apparatus comprising:
a separating optical system which separates the light supplied from the light source, into a first beam and a second beam in respective polarization states different from each other;
a varying optical system which is arranged in an optical path of at least one of the first beam and the second beam and which varies a phase difference distribution between the first beam and the second beam;
a combining optical system which combines the first beam and the second beam the phase difference distribution between which has been varied; and
a polarization state changing element which is arranged in an optical path of a compound beam obtained by the combining optical system and which changes a polarization state of the compound beam.

4. The illumination optical apparatus according to claim 1,
wherein the varying optical system comprises a first partial optical system which the first beam passes, and a second partial optical system which the second beam passes, and
wherein the combining optical system is disposed at a position of an intersection where an optical axis on the combining optical system side of the first partial optical system intersects with an optical axis on the combining optical system side of the second partial optical system.

5. The illumination optical apparatus according to claim 4,
wherein the combining optical system comprises a combining face for combining the first beam and the second beam, and
wherein the combining face is disposed at the position of the intersection.

6. The illumination optical apparatus according to claim 1, wherein the varying optical system varies a phase difference distribution of one of the first beam and the second beam.

7. The illumination optical apparatus according to claim 2,
wherein the polarization state changing element changes the first beam and the second beam into circular polarization states in respective directions opposite to each other, and
wherein polarization states in a beam section of the first beam and the second beam after combined have linear polarizations directed in respective directions different from each other.

8. The illumination optical apparatus according to claim 7, wherein the polarization state changing element is a quarter wave plate.

9. The illumination optical apparatus according to claim 1, wherein the varying optical system includes a reflecting member which is arranged in an optical path of the first beam or the second beam and a shape of a reflecting surface of which is partially deformable.

10. The illumination optical apparatus according to claim 1, wherein at least one of the separating optical system and the combining optical system is a polarization beam splitter.

11. The illumination optical apparatus according to claim 1, wherein the separating optical system includes a half mirror for dividing the light supplied from the light source, and an optical element which is arranged in an optical path of one beam resulting from the dividing by the half mirror and which rotates a polarization direction of the beam.

12. The illumination optical apparatus according to claim 1, wherein the first beam and the second beam are linearly polarized light beams with respective polarization directions orthogonal to each other.

13. The illumination optical apparatus according to claim 1, comprising a wave plate which is arranged in an optical path of the light entering the separating optical system and which adjusts a polarization direction of the light.

14. The illumination optical apparatus according to claim 1, comprising:
a light quantity distribution forming optical system which is arranged in an optical path of the light entering the separating optical system and which forms a light quantity distribution of light at a predetermined position in an illumination optical path of the illumination optical apparatus; and
a surface illuminant forming optical system which is arranged in an optical path of a compound beam obtained by the combining optical system and which effects wavefront division of the compound beam to form a surface illuminant with a light quantity distribution equivalent to the light quantity distribution of the light.

15. The illumination optical apparatus according to claim 14, wherein the varying optical system is disposed in the vicinity of an exit pupil of the illumination optical apparatus or a face equivalent to a face conjugate with the exit pupil.

16. The illumination optical apparatus according to claim 15, wherein the varying optical system includes a reflecting member which is disposed in an optical path of the first beam or the second beam and in the vicinity of the exit pupil of the illumination optical apparatus or the face equivalent to the face conjugate with the exit pupil, and a shape of a reflecting surface of which is partially deformable.

17. An exposure apparatus for illuminating a pattern with exposure light and exposing a substrate with the exposure light via the pattern and a projection optical system, the exposure apparatus comprising:
the illumination optical apparatus as set forth in claim 1,
wherein light from the illumination optical apparatus is used as the exposure light.

18. An optical unit for changing a polarization state of light supplied from a light source, the optical unit comprising:
a separating optical system which separates the light supplied from the light source, into a first beam and a second beam in respective polarization states different from each other;
a varying optical system which is arranged in an optical path of at least one of the first beam and the second beam and which varies a phase difference distribution between the first beam and the second beam;
a combining optical system which combines the first beam and the second beam between which the phase difference distribution has been varied; and
a polarization state changing element which is arranged in an optical path of a compound beam obtained by the combining optical system and which changes a polarization state of the compound beam.

19. The optical unit according to claim 18, wherein the varying optical system includes a reflecting member which is arranged in an optical path of the first beam or the second beam and a shape of a reflecting surface of which is partially deformable.

20. An illumination method for illuminating an illumination target surface with light supplied from a light source, the illumination method comprising:
separating the light supplied from the light source, into a first beam and a second beam in respective polarization states different from each other;
establishing a variable phase difference distribution between the first beam and the second beam; and
combining the first beam and the second beam the variable phase difference distribution between which has been established.

21. The illumination method according to claim 20, wherein the beams after combined are guided through a wave plate.

22. An illumination method for illuminating an illumination target surface with light supplied from a light source, the illumination method comprising:
separating the light supplied from the light source, into a first beam and a second beam in respective polarization states different from each other;
varying a phase difference distribution between the first beam and the second beam;
combining the first beam and the second beam between which the phase difference distribution has been varied; and
guiding a compound beam obtained by a combining optical system, through a polarization state changing element.

23. An exposure method for illuminating a pattern with exposure light and exposing a substrate with the exposure light via the pattern and a projection optical system, the exposure method comprising: employing the illumination method as set forth in claim 20, to use the light directed toward the illumination target surface, as the exposure light.

24. A device manufacturing method comprising:
forming a pattern of a photosensitive layer on the substrate, using the exposure method as set forth in claim 23; and
processing the substrate with the pattern formed thereon.

25. The illumination optical apparatus according to claim 3,
wherein the varying optical system comprises a first partial optical system which the first beam passes, and a second partial optical system which the second beam passes, and
wherein the combining optical system is disposed at a position of an intersection where an optical axis on the combining optical system side of the first partial optical system intersects with an optical axis on the combining optical system side of the second partial optical system.

26. The illumination optical apparatus according to claim 25,
wherein the combining optical system comprises a combining face for combining the first beam and the second beam, and
wherein the combining face is disposed at the position of the intersection.

27. The illumination optical apparatus according to claim 3, wherein the varying optical system varies a phase difference distribution of one of the first beam and the second beam.

28. The illumination optical apparatus according to claim 3,
wherein the polarization state changing element changes the first beam and the second beam into circular polarization states in respective directions opposite to each other, and
wherein polarization states in a beam section of the first beam and the second beam after combined have linear polarizations directed in respective directions different from each other.

29. The illumination optical apparatus according to claim 28, wherein the polarization state changing element is a quarter wave plate.

30. The illumination optical apparatus according to claim 3, wherein the varying optical system includes a reflecting member which is arranged in an optical path of the first beam or the second beam and a shape of a reflecting surface of which is partially deformable.

31. The illumination optical apparatus according to claim 3, wherein at least one of the separating optical system and the combining optical system is a polarization beam splitter.

32. The illumination optical apparatus according to claim 3, wherein the separating optical system includes a half mirror for dividing the light supplied from the light source, and an optical element which is arranged in an optical path of one beam resulting from the dividing by the half mirror and which rotates a polarization direction of the beam.

33. The illumination optical apparatus according to claim 3, wherein the first beam and the second beam are linearly polarized light beams with respective polarization directions orthogonal to each other.

34. The illumination optical apparatus according to claim 3, comprising a wave plate which is arranged in an optical path of the light entering the separating optical system and which adjusts a polarization direction of the light.

35. The illumination optical apparatus according to claim 3, comprising:
a light quantity distribution forming optical system which is arranged in an optical path of the light entering the separating optical system and which forms a light quantity distribution of light at a predetermined position in an illumination optical path of the illumination optical apparatus; and
a surface illuminant forming optical system which is arranged in an optical path of a compound beam obtained by the combining optical system and which effects wavefront division of the compound beam to form a surface illuminant with a light quantity distribution equivalent to the light quantity distribution of the light.

36. The illumination optical apparatus according to claim 35, wherein the varying optical system is disposed in the vicinity of an exit pupil of the illumination optical apparatus or a face equivalent to a face conjugate with the exit pupil.

37. The illumination optical apparatus according to claim 36, wherein the varying optical system includes a reflecting member which is disposed in an optical path of the first beam or the second beam and in the vicinity of the exit pupil of the illumination optical apparatus or the face equivalent to the face conjugate with the exit pupil, and a shape of a reflecting surface of which is partially deformable.

38. An exposure apparatus for illuminating a pattern with exposure light and exposing a substrate with the exposure light via the pattern and a projection optical system, the exposure apparatus comprising:
the illumination optical apparatus as set forth in claim 3,
wherein light from the illumination optical apparatus is used as the exposure light.

39. An exposure method for illuminating a pattern with exposure light and exposing a substrate with the exposure light via the pattern and a projection optical system, the exposure method comprising: employing the illumination method as set forth in claim 22, to use the light directed toward the illumination target surface, as the exposure light.

40. A device manufacturing method comprising:
forming a pattern of a photosensitive layer on the substrate, using the exposure method as set forth in claim 39; and
processing the substrate with the pattern formed thereon.
